(19) United States
(12) Patent Application Publication
(10) Pub. No.: US 2026/0223341 A1
(43) Pub. Date: Jul. 30, 2026

(54) MULTILAYER GASKET

(71) Applicant: NOLATO SILIKONTEKNIK AB, Hallsberg (SE)

(72) Inventors: Simon PETTERSSON, Orebro (SE); Magnus Carlsson, Pàlsboda (SE)

(73) Assignee: NOLATO SILIKONTEKNIK AB, Hallsberg (SE)

(21) Appl. No.: 19/144,844

(22) PCT Filed: Jan. 4, 2024
(86) PCT No.: PCT/SE2024/050006

§ 371 Date: Jun. 30, 2025

(30) Foreign Application Priority Data
Jan. 13, 2023 (SE) 2350024-2

(51) Int. Cl. H05K 9/00

(52) U.S. Cl. CPC H05K 9/0015; H05K 9/0083; H05K 9/0088

(57) ABSTRACT

The present disclosure relates to a gasket (100) for electromagnetic shielding, wherein the gasket comprises a first layer (1) and a second layer (2), wherein the electrical resistance of the first layer is lower than the electrical resistance of the second layer, and wherein the permeability of the second layer is higher than the permeability of the first layer. The present disclosure further relates to a method for manufacturing such a gasket.

### TECHNICAL FIELD

The present disclosure relates generally to a gasket for electromagnetic shielding. The gasket comprises at least two layers wherein the first layer has a lower electrical resistance than the second layer, and the second layer has a higher permeability than the first layer. Further, the present disclosure relates to a method for manufacturing such a gasket for electromagnetic shielding.

### BACKGROUND ART

With an increased demand for electronic devices such as computers, mobile phones and other wireless devices, there is a growing need for efficient and optimized components building up said electronic devices.

Electromagnetic interference, EMI, is a common problem when developing electronic devices. EMI, which can be present in the ambience or be emitted by electronic devices themselves, can disrupt or destroy for instance electrical systems and equipment present in electronic devices, and thus damage them.

A common solution is to enclose the EMI-emitting or EMI-sensitive component in an electrically conductive casing, thus creating a Faraday cage around said component. If said electrically conductive casing is made up of two or more mating surfaces, the gap or junction between the mating surfaces must be efficiently sealed by an EMI shielding gasket. However, the sealing gasket must at the same time be electrically conductive in order to ensure a functioning Faraday cage.

A proposed solution has been to join two surfaces by a gasket comprising a carrier material and an electrically conductive material dispersed in the carrier material. Traditionally, gaskets are manufactured by for instance dispensing a viscous material comprising the electrically conductive material on a first substrate, following by a treatment so that the viscous material assumes a non-viscous state, and thus a fixed shape. The gasket acts as an electrically conductive sealing joint between the first substrate and a second substrate as well as an EMI shield. Other methods of manufacturing gaskets used in the industry includes extruding, injection molding and die casting.

As electrically conductive materials may be expensive, there is a need within the industry to reduce the usage of expensive materials while still ensuring good EMI shielding properties of the gasket.

Another important requirement of gaskets for electromagnetic shielding is their ability to maintain the EMI shielding properties over time. It goes without saying that if the shielding ability of the gasket decreases significantly over time, the overall functionality of the electronic device comprising the gasket will be compromised.

As disclosed above, it can be required to shield EMI present in the ambience (i.e. to protect devices within a casing from outside EMI) or to avoid that EMI emitted from a component within a device interferes with other sensitive components within the device (i.e. to avoid EMI leakage from a casing). For certain applications, both these requirements are desired.

An example of a gasket for electromagnetic shielding is presented in GB2049718 A and WO03037057. However, none of these documents discloses a solution to improve the ageing properties of the gaskets disclosed.

As such, it would be desirable to provide a gasket for electromagnetic shielding with improved EMI shielding properties, and that preferably maintains the EMI shielding properties over time, i.e. a gasket with an improved ageing. Further on, it would also be preferable to reduce the usage of expensive electrically conductive materials, while at the same time maintaining good EMI shielding properties of the gasket

### SUMMARY OF INVENTION

An object of the present disclosure is to provide a gasket for electromagnetic shielding that exhibits improved ageing.

Another object of the present disclosure is to provide a gasket for electromagnetic shielding with a reduced amount of expensive electrically conductive particles.

Another object of the present disclosure is to provide a gasket for electromagnetic shielding comprising at least two layers, wherein the gasket exhibits a maintained or improved shielding ability compared to a gasket for electromagnetic shielding comprising one single layer of either one of the at least two layers.

Another object of the present disclosure is to provide a gasket for electromagnetic shielding that can be tailored to optimize the shielding properties depending on the placement of the source of EMI in relation to the gasket for electromagnetic shielding.

Another object of the present disclosure is to provide a method for manufacturing a gasket for electromagnetic shielding.

In a first aspect, the present disclosure is directed to a gasket for electromagnetic shielding, wherein the gasket comprises:
a) a first gasket layer comprising a first carrier material and a first kind of conductive particles, wherein said first gasket layer has a first electrical resistance value R1 and a first permeability value P1;
b) a second gasket layer comprising a second carrier material and a second kind of conductive particles, wherein said second gasket layer has a second electrical resistance value R2 and a second permeability value P2;
   wherein R1<R2 and P2>P1.

The carrier material may be an elastic material being in a non-viscous state. The carrier material acts as a carrier matrix for the conductive particles.

It has surprisingly been discovered that by combining at least two layers, wherein the electrical resistance value of the first layer is lower than the electrical resistance value of the second layer, and wherein the permeability value of the second layer is higher than the permeability value of the first layer, the EMI shielding performance of the gasket is improved. Without being bound to theory, it is believed that by combining at least two different layers having the above-mentioned properties, the shielding properties within the gasket will be different. As such, EMI that encounters a gasket according to the present disclosure will be subjected to different EMI shielding properties and thus different EMI shielding mechanisms. It is believed that the layer having the lower electrical resistance value and the lower permeability value will act as a reflective barrier against EMI, while the layer having the higher electrical resistance value and the higher permeability value will act as an absorbance barrier against EMI. As such, there is a synergistic effect in combining at least two layers having different electrical resistance values and permeability values, resulting in surprisingly good overall functionality of the gasket.

In the context of the present disclosure, “electrical resistance value” of a layer should be interpreted as a measured electrical resistance value of the layer when assessed individually, i.e. as a single layer gasket. When assessing the ratio between electrical resistance values of two layers, the thickness of two layers should be the same.

In the context of the present disclosure, “permeability value” of a layer should be interpreted as a measure of magnetization that a material obtains in response to an applied magnetic field.

The electrical resistance value may be calculated according to Oms' law. For instance, the electrical resistance may be measured by placing the gasket on a conductive surface, applying a square electrode on the gasket and measuring the voltage recorded by the applied electrode.

Moreover, it has also been discovered that by combining at least two layers having different properties according to what is disclosed herein, it is possible to reduce the amount of electrically conductive particles having a low electrical resistance value while still maintaining and/or improving the EMI shielding properties compared to if a single layer gasket comprising the same electrically conductive particles having a low electrical resistance value is used. As particles having a low electrical resistance are usually expensive, this reduces the manufacturing costs of the gasket.

The gasket may be in the shape of a bead having a longitudinal extension. The bead may also be in a rectangular shape, a triangular tapering shape or a D-formed shape for instance. However, the skilled person understands that also other shapes are possible.

A gasket according to the present disclosure may be utilized for shielding electronic devices and equipment, such as for instance a base station for mobile a telephone. In such a case, the gasket is arranged on a substrate after which the substrate is subsequently closed with a suitably designed mating substrate. The substrate may be a casing. The gasket will ensure that good electrical contact is provided between the two substrates, and also provide EMI shielding between the inside and outside of the gasket.

In one embodiment, the ratio between the first electrical resistance value R1 of the first layer and the second electrical resistance value R2 of the second layer is less than 0.5, more preferably less than 0.4.

By such a ratio, each layer is capable to conduct electrical current and as such ensure that a functioning Faraday cage is formed when two surfaces are joined by the gasket, while at the same time exhibiting different EMI shielding mechanisms between the at least two layers. As previously stated, it is important that the gasket is able to conduct electrical current in order to function as a gasket in a Faraday cage. As such, each layer of the at least two layers must be able to conduct electrical current. A ratio between the first electrical resistance value of the first layer and the second electrical resistance value of the second layer of less than 0.5, more preferably less than 0.4, ensures that each layer is able to conduct electrical current while at the same time ensure that each layer is sufficiently different to have different EMI-shielding properties.

In one embodiment, said first layer is configured to receive direct electromagnetic interference and said second layer is configured to receive electromagnetic interference that has passed through said first layer.

In the context of the present disclosure, the term “direct electromagnetic interference” should be interpreted as electromagnetic interference emitted from a main source of EMI that should be shielded by the gasket. For instance, the main source of EMI may be an ambience (outside or inside of an electronic device) or an EMI emitting electronic device. Therefore, the gasket according to the present disclosure is configured to be disposed in such a manner that the first layer (i.e., the layer with the lowest electrical resistance value), encounters electromagnetic interference from the main source of EMI to be shielded before the second layer. As such, the second layer receives EMI that has passed through the first layer.

As previously explained, it is believed that the first layer (the layer with the lower electrical resistance value) shields the EMI mainly by a reflecting mechanism, while the second layer (the layer with the higher electrical resistance value) shields the EMI mainly by an absorption mechanism. The combination of two different shielding mechanisms results in improved ageing and EMI shielding properties of the gasket.

In one embodiment, the first layer has an electrical resistance value of less than 4 Ohm, and the second layer has an electrical resistance value of less than 10 Ohm. In one embodiment, the electrical resistance value of the first layer is lower than the electrical resistance value of the second layer.

By such an exemplary gasket, a gasket with two layers having different EMI shielding mechanisms is provided. The combination of two different shielding mechanisms enables to reduce the amount of electrically conductive particles having a low conductivity while still maintaining or improving shielding properties compared to a single layer gasket comprising the same electrically conductive particles having a low conductivity. As electrically conductive particles having a low conductivity may be expensive, reducing their amount in the gasket greatly decreases the manufacturing costs.

In one embodiment, the first layer has an electrical resistance value of 0.1-100 megaOhm and the second layer has an electrical resistance value of 50-150 megaOhm, provided that the electrical resistance value of the first layer is lower than the electrical resistance value of the second layer.

In one embodiment, the gasket further comprises one or more additional layer(s) comprising a carrier material and electrically conductive particles.

By such an exemplary gasket, a gasket for electromagnetic shielding is provided with additional layers having specific shielding properties or electrically conductive properties. As such, the functionality of the gasket may be further improved and tailored depending on the desired usage of the gasket.

In one embodiment, the gasket further comprises an ingress protection (IP) layer, preferably said IP-layer comprises one or more of a silicone rubber and/or a thermoset polymer. Preferably, the ingress protection layer is arranged so to be in contact with the second layer.

The ingress protection layer provides the gasket with a layer ensuring protection from liquids (for instance water) and solids (for instance dust). While this layer does not provide a contribution to the EMI shielding properties, it further improves the overall functionality of the gasket by ensuring that the electronic device in which the gasket is used is protected from liquids and solids.

In one embodiment, the first and second carrier materials are, independently of each other, each selected from at least one of silicone rubber, and/or thermoset polymers.

The carrier material needs to be suitable to be used to form a gasket for electromagnetic shielding. In order to ensure a good sealing and shielding effects, the gasket must be compressed between the surfaces of a first and a second substrate to effectively joint the two surfaces. If properly joined, the gasket will ensure that electrical conductivity is achieved between the first and second substrate, and EMI shielding is achieved between the inside and the outside of the gasket, i.e. electromagnetic interference does not pass through the gasket.

Furthermore, a carrier material comprising conductive particles needs to exhibit a suitable viscosity so to be dispersed, injection molded, extruded, screen printed and/or press molded. Preferably, the first and second carrier materials both have a viscosity of 20-300 Pas.

In one embodiment, said first kind of conductive particles and said second kind of conductive particles are both metallic particles.

In one embodiment, said first layer comprises conductive particles comprising silver, copper, gold and/or aluminium. Preferably, the first layer comprises conductive particles comprising silver.

It is known that silver, copper, gold and/or aluminium exhibit low electrical resistance values. As such, without being bound to theory, it is believed that a first layer comprising conductive particles comprising silver, copper, gold and/or aluminium will act as an EMI reflecting shield.

Furthermore, a first layer comprising silver particles as conductive particles can improve the ageing properties of the gasket due to silver's antioxidant properties. As such, silver particles in the first layer can act as a protective layer for the second layer and thus improve the overall ageing of the gasket compared to a gasket for electromagnetic shielding comprising one single layer of either the first layer or the second layer according to the present disclosure.

In one embodiment, the second layer comprises conductive particles comprising nickel, ferrite, iron and/or cobalt. Preferably, the second layer comprising conductive particles comprises nickel.

It is known that nickel exhibits a higher electrical resistance value and a higher permeability value compared to other conductive materials. As previously explained, it is believed that a higher permeability value leads to an EMI absorbing effect. Therefore, it is believed that a second layer comprising conductive particles comprising nickel will act as an EMI absorbing shield.

In one embodiment, the ratio between the thickness of said first layer and the thickness of said second layer is between 1:20 to 20:1, preferably between 1:1 and 1:4.

The thickness of the first layer and the second layer may be selected depending on for instance the desired application of the gasket

In one embodiment, the first and said second layer each comprises 30-95 weight % of conductive particles, preferably 45-80 weight %.

In one embodiment, the first layer comprises 50-80 weight % conductive particles and 20-50 weight % carrier material.

In one embodiment, the second layer comprises 50-80 weight % conductive particles and 20-50 weight % carrier material. As previously described, the gasket needs to comprise a sufficiently high amount of particles in order to conduct electricity, while at the same time having a viscosity suitable for applying the composition forming the gasket in an industrially feasible manner. A too high amount of particles may lead to an excessive viscosity, a too low amount of particles will lead to impaired electrical conductivity.

In a second aspect, the present disclosure is directed to a method for manufacturing a gasket for electromagnetic shielding, wherein the method comprises the steps of:
i) providing a first composition comprising a first viscous material and a first kind of conductive particles;
ii) providing a second composition comprising a second viscous material and a second kind of conductive particles;
iii) applying said first composition as a first layer and said second composition as second layer to a substrate, by applying said first composition and said second composition in the form of a multilayer gasket;
iv) optionally applying additional compositions comprising a viscous material and/or conductive particles;
v) curing the applied compositions, thus forming a multilayer gasket wherein the first layer after curing has a first electrical resistance value R1 and a first permeability value P1, and wherein the second layer after curing has a second electrical resistance value R2 and a second permeability value P2; and
wherein R1<R2 and P2>P1.

A gasket manufactured according to a method of the present disclosure may be utilized for shielding electronic devices and equipment, such as for instance a base station for mobile telephone. In such a case, the gasket is arranged on a substrate after which the substrate is subsequently closed with a suitably designed mating substrate. The substrate may be a casing. The gasket will ensure that good electrical contact is provided between the two substrates, and also provide electromagnetic shielding between the inside and outside of the gasket.

It has surprisingly been discovered that by combining at least two layers, wherein the electrical resistance value of the first layer is lower than the electrical resistance value of the second layer, and wherein the permeability value of the second layer is higher than the permeability value of the first layer, the EMI shielding performance of the gasket manufactured according to the method is improved. Without being bound to theory, it is believed that by combining at least two different layers having the above mentioned properties, that the shielding properties within the gasket will be different. As such, EMI that encounters a gasket according to the present disclosure will be subjected to different EMI shielding properties and thus different EMI shielding mechanisms. It is believed that the layer having the lowest electrical resistance value and the lowest permeability value will act as a reflective barrier against EMI, while the layer having the highest electrical resistance value and the higher permeability value will act as an absorbance barrier against EMI. As such, there is a synergistic effect in combining at least two layers having different electrical resistance values and permeability values.

Moreover, it has also been discovered that by combining at least two layers having different properties according to what is disclosed herein, it is possible to reduce the amount of electrically conductive particles having a low electrical resistance value while still maintaining and/or improving the EMI shielding properties compared to if a single layer gasket comprising the same electrically conductive particles having a low electrical resistance value is used. As particles having a low electrical resistance are usually expensive, this reduces the manufacturing costs of gasket.

In one embodiment, the method is for manufacturing a gasket for electromagnetic shielding according to the first aspect.

In one embodiment, the ratio between the first resistance value of the first layer and the second resistance value of the second layer is less than 0.5, more preferably less than 0.4.

By such a ratio, each layer is capable to conduct electrical current and as such ensure that a functioning Faraday cage is formed when two surfaces are joined by the gasket, while at the same time exhibiting different EMI shielding mechanisms between the at least two layers formed by the at least two compositions. As previously stated, it is important that the gasket is able to conduct electrical current in order to function as a gasket in a Faraday cage. As such, each layer of the at least two layers must be able to conduct electrical current. A ratio between the first electrical resistance value of the first layer and the second electrical resistance value of the second layer of less than 0.5, more preferably less than 0.4, ensures that each layer is able to conduct electrical current while at the same time ensure that each layer is sufficiently different to have different EMI-shielding properties.

In one embodiment, step iii) comprises applying the first composition and the second composition to a substrate simultaneously.

By such an exemplary method, it is possible to apply the first and second composition in a single application step. This results in a faster and more economical manufacturing process.

In one embodiment, the first composition is applied to receive direct electromagnetic interference and said second composition is applied to receive electromagnetic interference that has passed through said first composition.

By such an exemplary method, the gasket is applied depending on a location of a main source of EMI to be shielded in relation to the location of the gasket on the substrate to which the gasket is applied on. To simplify, the first composition is according to such an exemplary method applied so to face the main source of EMI to be shielded when the gasket is in use.

As previously explained, it is believed that the first layer (the layer with the lower electrical resistance value) shields the EMI mainly by a reflecting mechanism, while the second layer (the layer with the higher permeability value) shields the EMI mainly by an absorption mechanism. The combination of two different shielding mechanisms results in improved ageing and EMI shielding properties of the gasket.

In one embodiment, the first composition and the second composition are applied by dispensing, injection molding, extrusion, screen printing and/or press molding.

In one embodiment, the viscosity of the first composition and the second composition is between 20-300 Pas.

In order to ensure a good applicability, it is important that the composition has a low viscosity. At the same time, the viscosity must be sufficiently high so that the composition, after applied to a substrate, retains its shape (height and width) and does not flow out before it has had time to harden or cure. The inventors have found that an optimal viscosity providing for both of the above mentioned requirements is between 20 and 300 Pas. In one exemplary method, the viscosity of the composition is between 20 and 150 Pas.

In one embodiment, the viscosity of the first composition is different from the viscosity of the second composition.

In one embodiment, the viscosity of the first composition is different from the viscosity of the second composition, so that the first composition and second composition are kept separate when applied to the substrate.

By such an exemplary method, a method for manufacturing a gasket is provided wherein the first and second compositions do not flow into each other during manufacturing. It is important that the compositions remain separate so to form two distinct layers as each layer will contribute with specific shielding properties.

In one embodiment, the applied compositions are cured at a temperature above 15 degrees C., preferably between 120-250 degrees C. for a period of at least 1-30 minutes or at a temperature between 15-60 degrees C. for a period of at least 6 hours.

By curing the gasket, it is ensured that a gasket with a fixed shape is formed.

### BRIEF DESCRIPTION OF DRAWINGS

The invention is now described, by way of example, with reference to the accompanying drawings, in which:

FIG. 1 illustrates a gasket according to the present disclosure applied to a substrate.

FIG. 2 illustrates two substrates joined by a gasket according to the present disclosure.

FIG. 3 schematically illustrates a method for manufacturing a gasket according to the present disclosure.

### DESCRIPTION OF EMBODIMENTS

The detailed description with reference to the disclosed embodiments are to be viewed as examples of combining specific features described above. It is to be understood that additional examples may be achieved by combining other and/or fewer/more features than in the disclosed embodiments. Hence, the figures disclose exemplary embodiments and not exclusive combinations. In this context is should also be noted that, for the sake of simplicity, all figures are schematically disclosed, as long as nothing else is said.

As used herein, “weight-%” refers to weight percent of the ingredient referred to of the total weight of the part, compound or composition referred to.

The present disclosure relates to a gasket for electromagnetic shielding comprising at least two layers, wherein the electrical resistance of the first layer is lower than the electrical resistance of the second layer, and wherein the permeability of the second layer is higher than the permeability of the first layer.

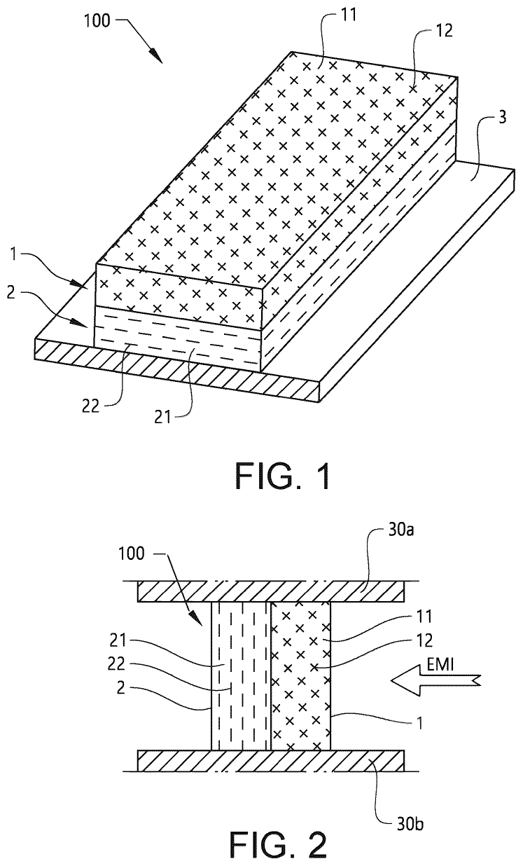

FIG. 1 illustrates a part-sectional view of a gasket 100 according to the present disclosure. The gasket 100 illustrated in FIG. 1 is arranged on a substrate 3. The gasket 100 comprises a first gasket layer 1 and a second gasket layer 2. The first gasket layer 1 comprises a first carrier material 11 and a first kind of conductive particles 12 within its structure. The first kind of conductive particles 12 are electrically conductive particles. The gasket further comprises a second gasket layer 2 comprising a second carrier material 21 and a second kind of conductive particles 22 within its structure. The second kind of conductive particles 22 are electrically conductive particles.

The first gasket layer 1 and the second gasket layer 2 each comprises an amount of conductive particles high enough so to be able to conduct electrical current. The first kind of conductive particles 12 and the second kind of conductive particles 22 are selected so that a resulting electrical resistance value R1 of the first gasket layer 1 is lower than a resulting electrical resistance value R2 of the second gasket layer 2. As such, as both layers comprise electrically conductive particles, each of the first gasket layer 1 and the second gasket layer 2 is able to conduct electrical current. However, the first gasket layer 1 is able to conduct electrical current better. Preferably, the ratio between R1 and R2 is less than 0.5.

The first kind of conductive particles 12 and the second kind of conductive particles 22 are further selected so that a resulting permeability value P1 of the first gasket layer 1 is lower than a resulting permeability value P2 of the second gasket layer 2. As such, the first gasket layer 1 does exhibit lower magnetic properties compared to the second gasket layer 2. Therefore, when shielding EMI, the first gasket layer 1 is able to better reflect the EMI while the second gasket layer 2 is able to better absorb the EMI.

The first kind of conductive particles 12 may be selected from silver, copper, gold and/or aluminium.

The second kind of conductive particles 22 may be selected from nickel, ferrite, iron and/or cobalt.

In the embodiment illustrated in FIG. 1, the gasket 100 is in the form of a rectangle having a longitudinal extension. However, the gasket 100 may also be in the form of a triangular tapering shape or a D-formed shape for instance.

Furter, in the embodiment illustrated in FIG. 1, the first layer 1 is applied over the second layer 2. However, in another embodiment not illustrated in FIG. 1, the first layer may be applied next to the second layer.

Turning now to FIG. 2 illustrating two substrates 30a and 30b joined by a gasket 100 according to the present disclosure. As the first gasket layer 1 and the second gasket layer 2 forming the gasket 100 are able to conduct electrical current, the gasket 100 ensures good electrical conductivity between substrate 30a and 30b, thus creating a Faraday cage. Furthermore, due to the electromagnetic shielding properties of the gasket 100, it also reduces the amount of electromagnetic waves EMI that are able to travel through the seal formed by the gasket 100.

In FIG. 2, electromagnetic waves EMI are illustrated as originating from an EMI emitting source located towards the first gasket layer 1 of the gasket 100. Due to the different kind of electrically conductive particles 12 and 22 comprised in the first and second gasket layer 1 and 2, the electromagnetic waves EMI will be subjected to different EMI shielding mechanisms when interacting with the gasket 100.

As previously explained, the first gasket layer 1 is an EMI reflecting barrier due to its lower electrical resistance value R1 and lower permeability value P1. The second gasket layer 2 is an EMI absorbing layer due to its higher permeability value P2.

It is therefore possible to orient the gasket 100 depending on the location of a main source of EMI to be shielded. Preferably, the first gasket layer 1 is oriented so that electromagnetic waves EMI to be shielded interact first with the first gasket layer 1.

Furthermore, it is also possible to improve the ageing of the gasket 100 by either orienting the gasket 100 so that the layer comprising the kind of electrically conductive particles having the best ageing performance is exposed to an open outside ambient, while the layer comprising the kind of electrically conductive particles having the inferior ageing performance is exposed to a sealed ambient, or by further comprising an additional ingress protection (IP) layer disposed so to protect the first layer and/or the second layer.

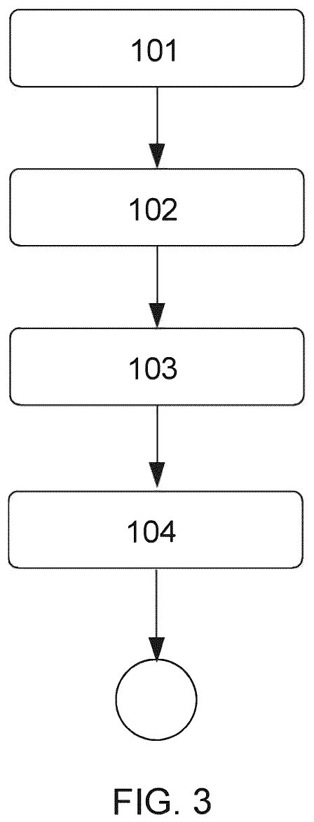

Turning now to FIG. 3 the method steps performed when manufacturing a gasket 100 according to the present disclosure are schematically illustrated. In a first step 101, a first composition is provided comprising a first viscous material and a first kind of conductive particles. In a second step 102, a second composition is provided comprising a second viscous material and a second kind of conductive particles.

The first composition and the second composition are in a third step 103 applied to a substrate. The first composition and the second composition may be applied by dispensing, injection molding, extrusion, screen printing and/or press molding. The first composition may be applied as a first layer and the second composition may be applied as second layer to the substrate, thereby forming a multilayer structure.

Preferably, the first and second compositions are applied to the substrate simultaneously.

In a fourth step 104, the applied compositions are cured. After curing, the first composition has a first electrical resistance value R1 and a first per permeability value P1, and wherein the second composition after curing has a second electrical resistance value R2 and a second permeability value P2. The relationship between R1, R2, P1 and P2 is R1<R2 and P2>P1.

### Examples

In the following example, 4 different gaskets are analysed. The gaskets comprise different compositions and the resulting electromagnetic shielding properties and electrical resistances are evaluated.

### Materials:

Composition A: Fluid silicone rubber 20-50 weight % and nickel particles 50-80 weight %
Composition B: Fluid silicone rubber 20-50 weight % and silver particles 50-80 weight %

4 gaskets are manufactured. Gasket G1 comprises a single layer of composition A Gasket G2 comprises a single layer of composition B. Gasket G3 and Gasket G4 are multilayer gaskets comprising a first layer comprising composition A and a second layer comprising composition B. All gaskets G1-G4 are manufactured by extrusion.

Gasket G1 has an electrical resistance of 60 mOmh and gasket G2 has an electrical resistance of 17 mOhm. The electrical resistance was measured by placing the gasket on a conductive surface. A square electrode 10×10 mm was applied on the gasket with a force of 6.5N. The resistance was measured in mΩ.

Gaskets G1-G4 are tested for the electromagnetic shielding properties. The test equipment has one aluminium bottom plate with a groove, and an aluminium top plate in order to enclose and compress a gasket placed in the groove. For each test, a gasket was put in the groove and enclosed with the top plate. The compression of the gasket was 35%. The gasket had 2 mm of its height exposed to the signal. Two cavities are located on opposite sides of the groove.

One short circuited probe is assembled in each cavity. A network analyser is connected and used to feed a signal into one of the cavities and to measure EMI inside the other cavity. The shielding effect of the gasket is measured in dB as the S21 response over the frequency range from 0.3 up to 20 GHz. The results for each gasket G1-G4 are shown in Table 1. For gaskets G3-G4, the gaskets are oriented so that the layer comprising composition B is facing the EMI emitting probe (inner layer) and the layer comprising composition A is facing away from the EMI emitting probe (outer layer)

The test was performed using unaged gasket (tO) and gasket that had been aged for 400 h (t1) and 1000 h (t2)

| | Conductive | Conductive | | | | |
|---|---|---|---|---|---|---|
| | particle inner | particle | | | | |
| | layer | outer layer | | Electromagnetic | | |
| | (thickness | (thickness | | shielding (dB) | | |
| | inner layer | outer layer | Thickness | (0.3-20 GHz) | | |
| Gasket | mm) | mm) | (mm) | tO | t1 | t2 |
| G1 | Ni (0.33) | N/A | 0.33 | 68 | 59 | 44 |
| G2 | Ag (0.1- | N/A | 0.1-0.2 | 103 | 85 | 72 |
| | 0.2) | | | | | |
| G3 | Ag (0.16 | Ni (0.33 | 0.49 | 115 | 114 | 111 |
| | mm) | mm) | | | | |
| G4 | Ag (0.09 | Ni (0.33 | 0.42 | 104 | 96 | 80 |
| | mm) | mm) | | | | |

As can be seen, the multilayer gasket G3 and G4, having an inner layer comprising silver particles facing the EMI emitting source, have improved shielding properties and improved ageing properties compared to the single layer gaskets G1 and G2. As previously explained, it is believed that silver acts as a protective layer for the inner layer, as well as being EMI reflecting.

In various example embodiments of a gasket 100 for electromagnetic shielding, the gasket 100 comprises: a first gasket layer 1 comprising a composition of a first carrier material 11 and a first kind of conductive particles 12, wherein said first gasket layer 1 has a first electrical resistance value R1 and a first permeability value P1; a second gasket layer 2 comprising a composition of a second carrier material 21 and a second kind of conductive particles 22, wherein said second layer 2 has a second electrical resistance value R2 and a second permeability value P2; wherein R1<R2 and P2>P1 and wherein said first and second carrier materials are, independently of each other, each selected from at least one of silicone rubber and/or thermoset polymers. The first gasket layer 1 and second gasket layer 2 are here forming the gasket 100. In other example embodiments additional gasket layers may be present.

We claim:

1. A gasket (100) for electromagnetic shielding, wherein the gasket (100) comprises:
a) a first gasket layer (1) comprising a composition of a first carrier material (11) and a first kind of conductive particles (12), wherein said first layer (1) has a first electrical resistance value R1 and a first permeability value P1;
b) a second gasket layer (2) comprising a composition of a second carrier material (21) and a second kind of conductive particles (22), wherein said second layer (2) has a second electrical resistance value R2 and a second permeability value P2;
wherein R1<R2 and P2>P1 and wherein said first and second carrier materials are, independently of each other, each selected from at least one of silicone rubber and/or thermoset polymers.

2. The gasket (100) according to claim 1, wherein the ratio between said first electrical resistance value R1 and said second electrical resistance value R2 is less than 0.5.

3. The gasket (100) according to claim 1, wherein said first gasket layer (1) is configured to receive direct electromagnetic interference and said second gasket layer (2) is configured to receive electromagnetic interference that has passed through said first layer (1).

4. The gasket (100) according to claim 1, wherein the first gasket layer (1) has an electrical resistance value R1 of less than 4 Ohm and the second gasket layer (2) has an electrical resistance value R2 of less than 10 Ohm.

5. The gasket (100) according to claim 1, wherein the gasket further comprises one or more additional layer(s) comprising a carrier material and electrically conductive particles.

6. The gasket (100) according to claim 1, wherein the gasket further comprises an ingress protection (IP) layer.

7. The gasket (100) according to claim 1, wherein said first kind of conductive particles (12) and said second kind of conductive particles (22) are both metallic particles.

8. The gasket (100) according to claim 1, wherein said first layer (1) comprises conductive particles comprising silver, copper, gold and/or aluminium.

9. The gasket (100) according to claim 1, wherein said second layer (2) comprises conductive particles comprising nickel, ferrite, iron and/or cobalt.

10. The gasket (100) for electromagnetic shielding according to claim 1, wherein the ratio between the thickness of said first layer and the thickness of said second layer is between 1:20 to 20:1.

11. The gasket (100) for electromagnetic shielding according to claim 1, wherein said first and said second gasket layer each comprises 30-95 weight % of conductive particles.

12. A method for manufacturing a gasket for electromagnetic shielding, wherein the method comprises the steps of:
i) providing a first composition comprising a first viscous material and a first kind of conductive particles;
ii) providing a second composition comprising a second viscous material and a second kind of conductive particles;
iii) applying said first composition as a first gasket layer and said second composition as second gasket layer to a substrate, by applying said first composition and said second composition in the form of a multilayer gasket;
iv) curing the applied compositions, thus forming a multilayer gasket wherein the first gasket layer after curing has a first electrical resistance value R1 and a first permeability value P1, and wherein the second gasket layer after curing has a second electrical resistance value R2 and a second permeability value P2; and
wherein R1<R2 and P2>P1 and wherein said viscous material is silicon rubber and/or thermoset polymer.

13. The method according to claim 12, wherein the ratio between the first electrical resistance value and the second electrical resistance value is less than 0.5.

14. The method according to claim 12, wherein step iii) comprises applying the first composition and the second composition to a substrate simultaneously.

15. The method according to claim 12, wherein said first composition is applied to receive direct electromagnetic interference and said second composition is applied to receive electromagnetic interference that has passed through said first composition.

16. The method according to claim 12, wherein said first composition and said second composition are applied by dispensing, injection molding, extrusion, screen printing and/or press molding.

17. The method according to claim 12, wherein the viscosity of said first composition and the viscosity of said second composition are both between 20-300 Pas.

18. The method according to claim 12, wherein the viscosity of the first composition is different from the viscosity of the second composition, so that the first composition and second composition are kept separate.

19. The method according to claim 12, wherein the applied compositions are cured at a temperature above 15 degrees C.

20. The method according to claim 12, wherein the method comprises an additional step of applying additional composition comprising a viscous material and/or conductive particles prior to curing the applied compositions.
